(19) United States
(12) Patent Application Publication
(10) Pub. No.: US 2025/0379051 A1
(43) Pub. Date: Dec. 11, 2025

(54) METHOD OF MANUFACTURING SEMICONDUCTOR DEVICE

(71) Applicant: Kioxia Corporation, Tokyo (JP)

(72) Inventors: Yuta SAITO, Yokkaichi Mie (JP); Daichi NISHIKAWA, Mie Mie (JP); Shinji MORI, Nagoya Aichi (JP)

(21) Appl. No.: 19/070,363

(22) Filed: Mar. 4, 2025

(30) Foreign Application Priority Data
Jun. 11, 2024 (JP) 2024-094356

(51) Int. Cl. H01L 21/02

(52) U.S. Cl. CPC H01L 21/02694; H01L 21/02527; H01L 21/02532

(57) ABSTRACT

According to one embodiment, a method of manufacturing a semiconductor device includes forming a semiconductor layer containing a plurality of metal atoms. The method further includes forming a first layer other than a silicon (Si) layer on the semiconductor layer as a layer containing a main component element different from a main component element of the semiconductor layer. The method further includes annealing the semiconductor layer to move some of the metal atoms in the semiconductor layer into the first layer. The method further includes removing the first layer after some of the metal atoms have been moved into the first layer.

### CROSS-REFERENCE TO RELATED APPLICATION(S)

This application is based upon and claims the benefit of priority from Japanese Patent Application No. 2024-094356, filed Jun. 11, 2024, the entire contents of which are incorporated herein by reference.

### FIELD

Embodiments described herein relate generally to a method of manufacturing a semiconductor device.

### BACKGROUND

When metal atoms contained in a semiconductor layer are removed to a layer called a getter layer, it is desirable that the getter layer can be suitably removed after the removal of the metal atoms. For example, it is desirable that the getter layer can be easily removed and the getter layer can be removed while preventing damage to the semiconductor layer.

### BRIEF DESCRIPTION OF THE DRAWINGS

FIG. 1 is a cross-sectional view showing a structure of a semiconductor device according to a first embodiment.

FIG. 2 is an enlarged cross-sectional view showing the structure of the

semiconductor device according to the first embodiment.

FIGS. 3-4 are cross-sectional views showing a method of manufacturing the semiconductor device according to the first embodiment.

FIGS. 5-14 are cross-sectional views showing the method of forming a memory cell array of the semiconductor device according to the first embodiment.

FIGS. 15-16 are cross-sectional views showing a method of manufacturing the semiconductor device according to a modification example of the first embodiment.

FIGS. 17-19 are cross-sectional views showing a method of manufacturing a semiconductor device according to a comparative example.

FIGS. 20-27 are cross-sectional views showing a method of manufacturing a semiconductor device according to a second embodiment.

### DETAILED DESCRIPTION

Embodiments provide a method of manufacturing a semiconductor device in which a getter layer can be suitably removed.

In general, according to one embodiment, a method of manufacturing a semiconductor device includes forming a semiconductor layer containing a plurality of metal atoms. The method further includes forming a first layer other than a silicon (Si) layer on the semiconductor layer as a layer containing a main component element different from a main component element of the semiconductor layer. The method further includes annealing the semiconductor layer to move some of the metal atoms in the semiconductor layer into the first layer. The method further includes removing the first layer after some of the metal atoms have been moved into the first layer.

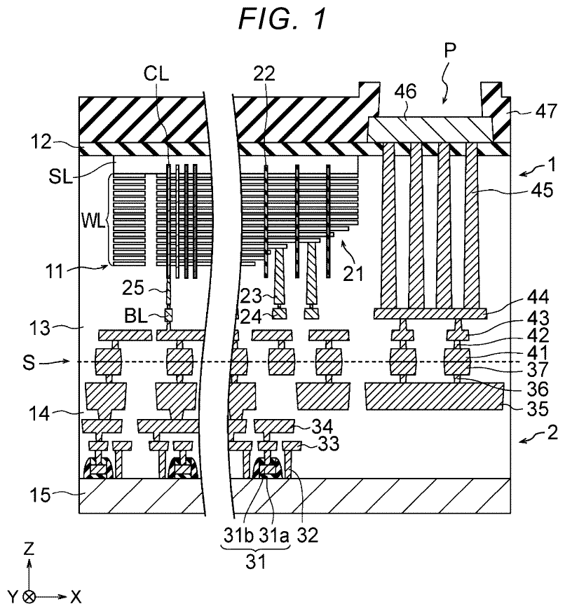

Hereinafter, embodiments of the present disclosure will be described with reference to the drawings. In FIGS. 1 to 27, the same components are denoted by the same reference symbols, and redundant description will be omitted.

### First Embodiment

FIG. 1 is a cross-sectional view showing a structure of a semiconductor device according to a first embodiment.

The semiconductor device according to the present embodiment includes, for example, a three-dimensional semiconductor memory. The semiconductor device of the present embodiment is manufactured by bonding an array wafer including an array chip 1 and a circuit wafer including a circuit chip 2, as will be described below.

The array chip 1 includes a memory cell array 11 including a plurality of memory cells, an insulating film 12 on the memory cell array 11, and an interlayer insulating film 13 below the memory cell array 11. The insulating film 12 is, for example, a silicon oxide film (SiO₂ film). The interlayer insulating film 13 is, for example, a stacked film including a SiO₂ film and another insulating film.

The circuit chip 2 is provided under the array chip 1. A reference sign S indicates a bonding surface between the array chip 1 and the circuit chip 2. The circuit chip 2 includes an interlayer insulating film 14 below the interlayer insulating film 13 and a substrate 15 below the interlayer insulating film 14. The interlayer insulating film 14 is, for example, a stacked film including a SiO₂ film and another insulating film. The substrate 15 is, for example, a semiconductor substrate such as a silicon (Si) substrate.

FIG. 1 shows X and Y directions parallel to a surface of the substrate 15 and perpendicular to each other, and a Z direction perpendicular to the surface of the substrate 15. The X direction, the Y direction, and the Z direction intersect with each other. In the present specification, a +Z direction is regarded as an upward direction, and a −Z direction is regarded as a downward direction. The −Z direction may or may not coincide with a gravity direction.

The array chip 1 includes a plurality of word lines WL as a plurality of electrode layers in the memory cell array 11. FIG. 1 shows a step structure portion 21 in the memory cell array 11 and a plurality of beam portions 22 provided in the step structure portion 21. Each word line WL is electrically connected to a word line wiring layer 24 via a contact plug 23. Each columnar portion CL that penetrates the plurality of word lines WL is electrically connected to a bit line BL via a via plug 25 and is electrically connected to a source line SL. The bit line BL is provided below the plurality of word lines WL, and the source line SL is provided above the plurality of word lines WL.

The circuit chip 2 includes a plurality of transistors 31. Each transistor 31 includes a gate insulating film 31a and a gate electrode 31b provided in order on the substrate 15, and a source diffusion layer (not shown) and a drain diffusion layer (not shown) provided in the substrate 15. In addition, the circuit chip 2 includes a plurality of contact plugs 32 provided on the gate electrodes 31b, the source diffusion layers, or the drain diffusion layers of the plurality of transistors 31. In addition, the circuit chip 2 includes a wiring layer 33, a wiring layer 34, and a wiring layer 35. The wiring layer 33 includes a plurality of wires and is provided on the plurality of contact plugs 32. The wiring layer 34 includes a plurality of wires and is provided above the wiring layer 33. The wiring layer 35 includes a plurality of wires and is provided above the wiring layer 34.

The circuit chip 2 further includes a plurality of via plugs 36 provided on the wiring layer 35 and a plurality of metal pads 37 provided on the plurality of via plugs 36. The metal pad 37 is, for example, a metal layer including a copper (Cu) layer. The circuit chip 2 functions as a control circuit (e.g., logical circuit) that controls the operation of the array chip 1. The control circuit includes the transistor 31 and the like and is electrically connected to the metal pad 37.

The array chip 1 includes a plurality of metal pads 41 provided on the plurality of metal pads 37 and a plurality of via plugs 42 provided on the plurality of metal pads 41. The metal pad 41 is, for example, a metal layer including a Cu layer. In addition, the array chip 1 includes a wiring layer 43 and a wiring layer 44. The wiring layer 43 includes a plurality of wires and is provided on the plurality of via plugs 42. The wiring layer 44 includes a plurality of wires and is provided above the wiring layer 43. The above-described bit line BL is provided in the wiring layer 44. In addition, the control circuit is electrically connected to the memory cell array 11 via the metal pads 41 and 37, and the like, and controls the operation of the memory cell array 11 via the metal pads 41 and 37, and the like.

The array chip 1 further includes a plurality of via plugs 45 provided on the wiring layer 44 and a metal pad 46 provided on the plurality of via plugs 45 and the insulating film 12. In addition, the array chip 1 includes a passivation insulating film 47 provided on the metal pad 46 and the insulating film 12. The metal pad 46 is, for example, a metal layer including a Cu layer, and functions as an external connection pad (e.g., bonding pad) of the semiconductor device of the present embodiment. The passivation insulating film 47 is, for example, a stacked film including a SiO₂ film and a silicon nitride (SiN) film, and has an opening P that exposes the upper surface of the metal pad 46. The metal pad 46 can be electrically connected to the mounting substrate or another device by a bonding wire, a solder ball, a metal bump, or the like through the opening P.

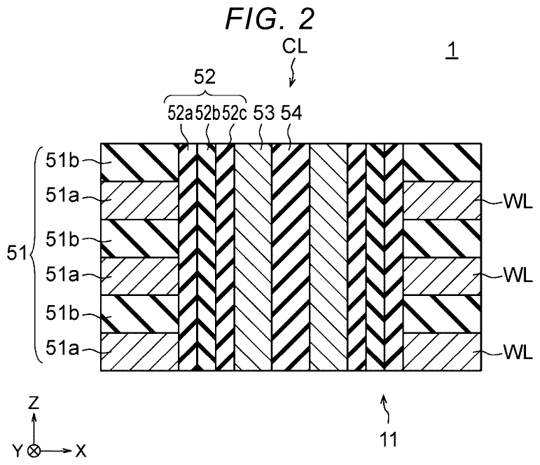

FIG. 2 is an enlarged cross-sectional view showing the structure of the semiconductor device according to the first embodiment.

FIG. 2 shows the memory cell array 11 shown in FIG. 1. The memory cell array 11 includes a stacked film 51 including a plurality of electrode layers 51a and a plurality of insulating films 51b alternately stacked in the Z direction. The plurality of electrode layers 51a function as, for example, the word lines WL. Each electrode layer 51a is, for example, a metal layer including a tungsten (W) layer. Each insulating film 51b is, for example, a SiO₂ film.

FIG. 2 further shows one of the plurality of columnar portions CL shown in FIG. 1. Each columnar portion CL includes a memory insulating film 52, a channel semiconductor layer 53, and a core insulating film 54 provided in order on the side surface of the stacked film 51. The memory insulating film 52 includes a block insulating film 52a, a charge storage layer 52b, and a tunnel insulating film 52c provided in order on the side surface of the stacked film 51. The block insulating film 52a is, for example, a SiO₂ film. The charge storage layer 52b is, for example, an insulating film such as a SiN film. The charge storage layer 52b may be a semiconductor layer such as a polysilicon layer. The tunnel insulating film 52c is, for example, a SiO₂ film. The channel semiconductor layer 53 is, for example, a polysilicon layer. The channel semiconductor layer 53 functions as a channel of the memory cell. The core insulating film 54 is, for example, a SiO₂ film.

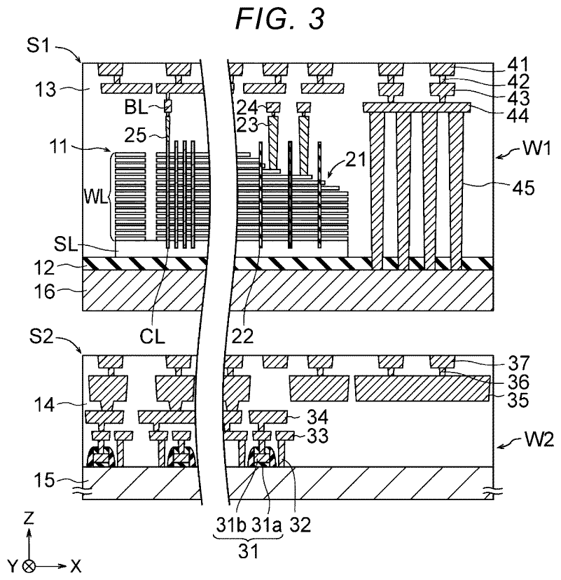

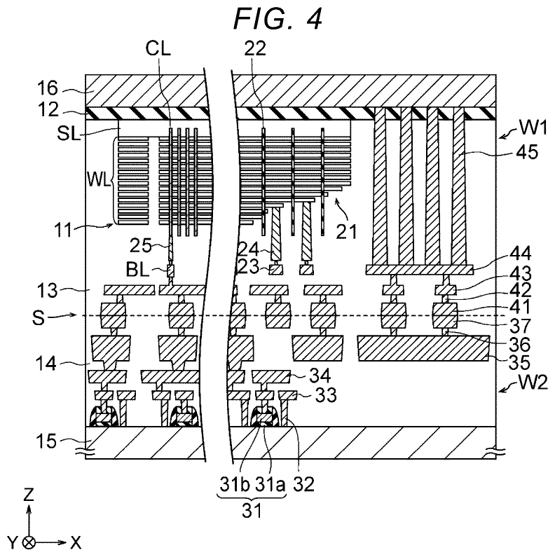

FIGS. 3 and 4 are cross-sectional views showing a method of manufacturing a semiconductor device according to the first embodiment.

FIG. 3 shows an array wafer W1 including a plurality of array chips 1 and a circuit wafer W2 including a plurality of circuit chips 2. The direction of the array wafer W1 in FIG. 3 is opposite to the direction of the array chip 1 in FIG. 1. In the present embodiment, a semiconductor device is manufactured by bonding the array wafer W1 and the circuit wafer W2. FIG. 3 shows the array wafer W1 before the orientation is reversed for bonding, and FIG. 1 shows the array chip 1 after the orientation of the array wafer W1 including the array chip 1 is reversed for bonding and then bonded and diced.

In FIG. 3, a reference sign S1 indicates an upper surface of the array wafer W1, and a reference sign S2 indicates an upper surface of the circuit wafer W2. The array wafer W1 includes a substrate 16 provided below the insulating film 12. The substrate 16 is, for example, a semiconductor substrate such as a Si substrate.

In the present embodiment, first, as shown in FIG. 3, the memory cell array 11, the insulating film 12, the interlayer insulating film 13, the metal pad 41, and the like are formed on the substrate 16 of the array wafer W1, and the interlayer insulating film 14, the transistor 31, the metal pad 37, and the like are formed on the substrate 15 of the circuit wafer W2. Next, as shown in FIG. 4, the array wafer W1 and the circuit wafer W2 are bonded to each other by first applying mechanical pressure while the surface S1 and the surface S2 face each other. Thereby, the interlayer insulating film 13 and the interlayer insulating film 14 also face each other. Next, the array wafer W1 and the circuit wafer W2 are annealed. Thereby, the metal pad 41 and the metal pad 37 are bonded to each other and the interlayer insulating film 13 and the interlayer insulating film 14 are bonded to each other. In this manner, the substrate 16 and the substrate 15 are bonded to each other with the interlayer insulating films 13 and 14 interposed therebetween.

Thereafter, the substrate 16 is removed by chemical mechanical polishing (CMP), and the substrate 15 is thinned by CMP, and then the array wafer W1 and the circuit wafer W2 are cut into a plurality of chips (e.g., by dicing). In this manner, the semiconductor device shown in FIG. 1 is manufactured. The metal pad 46 and the passivation insulating film 47 are formed on the insulating film 12 after the removal of the substrate 16 and the thinning of the substrate 15.

Although FIG. 1 shows a boundary surface between the interlayer insulating film 13 and the interlayer insulating film 14 and a boundary surface between the metal pad 41 and the metal pad 37, it is generally observed that these boundary surfaces are not observed after the above annealing. However, the position of the boundary surface can be estimated by detecting, for example, the inclination of the side surface of the metal pad 41 or the side surface of the metal pad 37, or the positional deviation between the side surface of the metal pad 41 and the side surface of the metal pad 37.

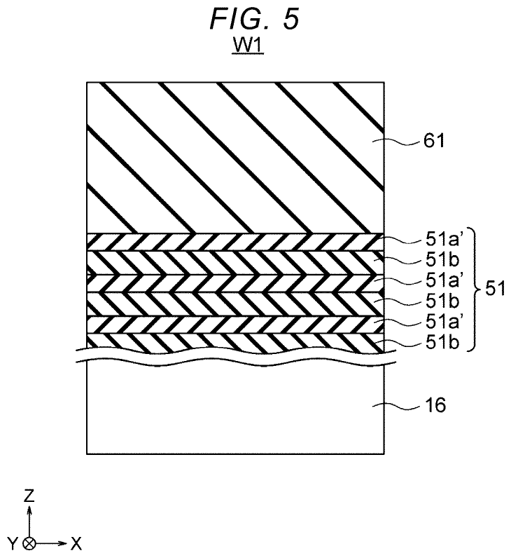

FIGS. 5 to 14 are cross-sectional views showing a method of manufacturing a semiconductor device according to the first embodiment. FIGS. 5 to 14 show details of the step of forming the memory cell array 11 in FIG. 3.

First, the stacked film 51 is formed above the substrate 16 of the array wafer W1, and the insulating film 61 is formed on the stacked film 51 (FIG. 5). The stacked film 51 is formed by alternately forming the plurality of insulating films 51b and a plurality of sacrificial layers 51a′ on the substrate 16. Each sacrificial layer 51a′ is, for example, a SiN film. The insulating film 61 is, for example, a SiO₂ film.

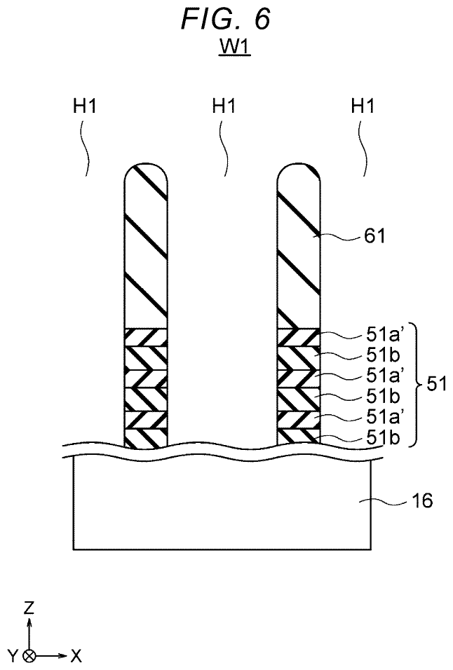

Next, a plurality of memory holes H1 are formed in the insulating film 61 and the stacked film 51 by lithography and reactive ion etching (RIE) (FIG. 6). Each of the memory holes H1 has a shape extending in the Z direction and a circular shape in a plan view. Each of the memory holes H1 according to the present embodiment penetrates the insulating film 61 and the stacked film 51 in the Z direction.

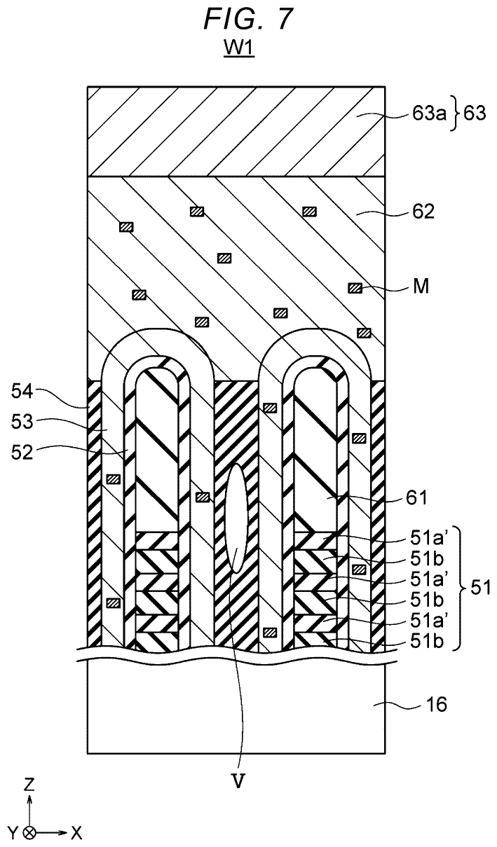

Next, the memory insulating film 52, the channel semiconductor layer 53, the core insulating film 54, a cap semiconductor layer 62, and a getter layer 63 are formed in order on the entire surface of the substrate 16 (FIG. 7). As a result, the memory insulating film 52, the channel semiconductor layer 53, and the core insulating film 54 are formed in order on the side surfaces of the stacked film 51 and the insulating film 61 in each memory hole H1. In FIG. 7, the memory insulating film 52 and the channel semiconductor layer 53 are further formed in order on the upper surface of the insulating film 61. FIG. 7 further shows a void V formed in the core insulating film 54.

In the step shown in FIG. 7, the memory insulating film 52, the channel semiconductor layer 53, and the core insulating film 54 are formed on the side surfaces of the stacked film 51 and the insulating film 61 and on the upper surface of the insulating film 61, and then the core insulating film 54 is removed from the upper surface of the insulating film 61. As a result, the upper surface of the channel semiconductor layer 53 becomes exposed. Thereafter, the cap semiconductor layer 62 and the getter layer 63 are formed in order on the channel semiconductor layer 53 and the core insulating film 54. In FIG. 7, the lower surface of the cap semiconductor layer 62 is in contact with the upper surface of the channel semiconductor layer 53, and the lower surface of the getter layer 63 is in contact with the upper surface of the cap semiconductor layer 62.

The cap semiconductor layer 62 is, for example, a polysilicon layer like the channel semiconductor layer 53. The channel semiconductor layer 53 and the cap semiconductor layer 62 include metal atoms M in the step shown in FIG. 7. FIG. 7 schematically shows the metal atoms M contained in the channel semiconductor layer 53 and the cap semiconductor layer 62. The metal atoms M are, for example, nickel (Ni) atoms, cobalt (Co) atoms, manganese (Mn) atoms, titanium (Ti) atoms, chromium (Cr) atoms, ruthenium (Ru) atoms, iridium (Ir) atoms, palladium (Pd) atoms, iron (Fe) atoms, or platinum (Pt) atoms. The channel semiconductor layer 53 and the cap semiconductor layer 62 of the present embodiment are un-doped Si layers that do not contain either p-type impurity atoms or n-type impurity atoms. The channel semiconductor layer 53 and the cap semiconductor layer 62 are examples of a semiconductor layer.

The channel semiconductor layer 53 and the cap semiconductor layer 62 of the present embodiment are formed by crystallizing an amorphous silicon layer containing the metal atoms M. As a result, the channel semiconductor layer 53 and the cap semiconductor layer 62 become a polysilicon layer containing the metal atoms M. According to the present embodiment, by forming the channel semiconductor layer 53 and the cap semiconductor layer 62 to contain the metal atoms M and crystallizing the channel semiconductor layer 53 and the cap semiconductor layer 62, it is possible to increase the grain size of the crystal grains in the channel semiconductor layer 53 and the cap semiconductor layer 62. The annealing for crystallizing the channel semiconductor layer 53 and the cap semiconductor layer 62 may be performed at a low temperature in order to increase the grain size of the crystal grains in the channel semiconductor layer 53 and the cap semiconductor layer 62.

In the present embodiment, the channel semiconductor layer 53 and the cap semiconductor layer 62 are Si layers, and the getter layer 63 is a layer other than the Si layer. The getter layer 63 contains, for example, carbon (C), and contains C as a main component element in the present embodiment. Therefore, in the getter layer 63 of the present embodiment, a composition ratio of C is higher than the composition ratio of any other element. The getter layer 63 is, for example, a C layer, and the C layer may further contain an impurity element. The impurity element is, for example, boron (B), phosphorus (P), arsenic (As), nitrogen (N), oxygen (O), or silicon (Si). The getter layer 63 is an example of a first layer. Each of the channel semiconductor layer 53 and the cap semiconductor layer 62 of the present embodiment is a Si layer, and specifically, is a layer (hereinafter, referred to as a “layer A”) containing only Si element or a layer (hereinafter, referred to as a “layer B”) containing Si element as a main component element and containing an element other than Si element as an impurity element. Meanwhile, the getter layer 63 of the present embodiment is a layer other than the Si layer, and specifically, is a layer that is neither the layer A nor the layer B. The getter layer 63 of the present embodiment contains a main component element different from the main component element in the channel semiconductor layer 53 and the cap semiconductor layer 62.

The getter layer 63 may contain germanium (Ge) instead of C, and may contain, for example, Ge as a main component element and B, P, As, N, O, or Si as an impurity element. The getter layer 63 in this case is, for example, a Ge layer.

The getter layer 63 is formed as the amorphous layer 63a in the step shown in FIG. 7. The amorphous layer 63a is, for example, an amorphous C layer. The amorphous layer 63a may be an amorphous Ge layer instead of the amorphous C layer.

The channel semiconductor layer 53 and the cap semiconductor layer 62 may contain only one type of metal atom M, or may contain two or more types of metal atoms M. In addition, the getter layer 63 may contain only one of C and Ge as a main component element, or may contain both C and Ge. In addition, the getter layer 63 may contain only one of B, P, As, N, O, or Si as the impurity element, or may contain two or more of B, P, As, N, O, or Si.

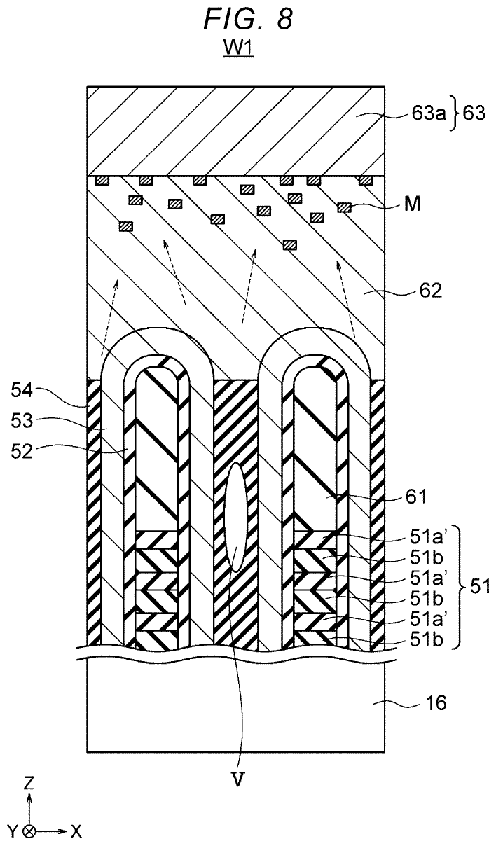

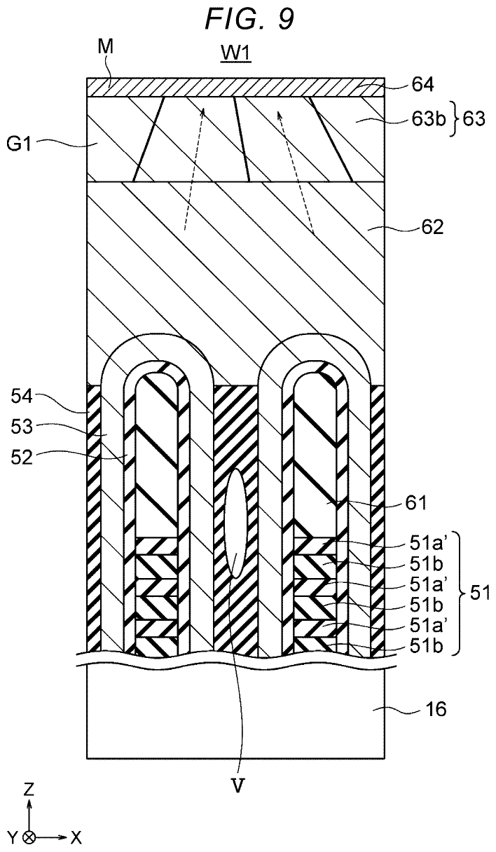

Next, the channel semiconductor layer 53, the cap semiconductor layer 62, the getter layer 63, and the like are annealed (FIG. 8). As a result, at least some of the metal atoms M in the channel semiconductor layer 53 and the cap semiconductor layer 62 can be moved to the vicinity of the getter layer 63 (FIG. 8), and the metal atoms M can be further moved to the inside or the surface (upper surface) of the getter layer 63 (FIG. 9). In FIG. 9, the metal atoms M move to the surface of the getter layer 63 to form the metal layer 64 containing the metal atoms M. In the present embodiment, the metal layer 64 is formed on the surface of the getter layer 63 between the annealing shown in FIGS. 8 and 9. As a result, at least some of the metal atoms M in the channel semiconductor layer 53 and the cap semiconductor layer 62 are removed from the channel semiconductor layer 53 and the cap semiconductor layer 62, and the concentration of the metal atoms M in the channel semiconductor layer 53 and the cap semiconductor layer 62 is reduced. This annealing is also called a gettering annealing.

The getter layer 63 changes from the amorphous layer 63a to the crystallization layer 63b during the annealing shown in FIGS. 8 and 9. The crystallization layer 63b is, for example, a polycrystalline C layer. Examples of the polycrystalline C layer include a graphene layer. FIG. 9 shows a plurality of crystal grains G1 contained in the crystallization layer 63b. When the amorphous layer 63a is an amorphous Ge layer, the crystallization layer 63b is, for example, a polycrystalline Ge layer.

The annealing shown in FIGS. 8 and 9 is performed at, for example, 300° C. to 1200° C. By setting the annealing temperature to be relatively high, for example, it is possible to generate the gettering shown in FIGS. 8 and 9. By setting the annealing temperature to be relatively low, for example, it is possible to avoid the dissolution of the Si layer. In the present embodiment, the annealing is performed at, for example, 600° C. to 1000° C.

The annealing shown in FIGS. 8 and 9 is performed in an atmosphere including, for example, an inert gas. Thereby, for example, it is possible to prevent oxygen-based gas from adversely affecting the layer in the array wafer W1 during the annealing. The annealing is performed in an atmosphere containing, for example, an argon (Ar) gas, a neon (Ne) gas, a xenon (Xe) gas, a nitrogen (N₂) gas, a hydrogen (H₂) gas, or a deuterium (D₂) gas.

In the gettering shown in FIGS. 8 and 9, the following phenomenon may occur. For example, the metal atoms M contained in the channel semiconductor layer 53 and the cap semiconductor layer 62 are sucked into the getter layer 63, and thus, the metal atoms M are removed from the channel semiconductor layer 53 and the cap semiconductor layer 62. In addition, as shown in FIG. 8, the metal atoms M contained in the channel semiconductor layer 53 and the cap semiconductor layer 62 form a region containing the metal atoms M at a high concentration near the lower surface of the getter layer 63, and this region is interchanged with the getter layer 63 in an up-down direction. When this region is regarded as the metal layer 64, it can be considered that the metal layer 64 has moved from the lower surface side of the getter layer 63 to the upper surface side, that is, the position of the metal layer 64 has been exchanged with the position of the getter layer 63 (FIG. 9). This effect is also called layer exchange. The layer exchange may be expressed as the metal atoms M contained in the channel semiconductor layer 53 and the cap semiconductor layer 62 being sucked up to the surface (upper surface) of the getter layer 63. The layer exchange occurs, for example, when the getter layer 63 is the C layer.

It is desirable that the getter layer 63 of the present embodiment is formed on the cap semiconductor layer 62 such that an unnecessary film (for example, a SiO₂ film or a SiN film) is not interposed between the cap semiconductor layer 62 and the getter layer 63. As a result, it is possible to prevent an unnecessary film from inhibiting the gettering. In the present embodiment, after the surface (upper surface) of the cap semiconductor layer 62 is processed with a chemical solution such as hydrofluoric acid, the getter layer 63 is formed on the cap semiconductor layer 62. As a result, it is possible to remove an unnecessary film from the surface of the cap semiconductor layer 62, and it is possible to avoid the interposition of an unnecessary film between the cap semiconductor layer 62 and the getter layer 63. An example of an unnecessary film is a natural oxide film. It is desirable that the step of treating the surface of the cap semiconductor layer 62 with a chemical solution and the step of forming the getter layer 63 are performed in-situ in the same chamber. As a result, it is possible to prevent the formation of a new unnecessary film on the surface of the cap semiconductor layer 62 between these steps.

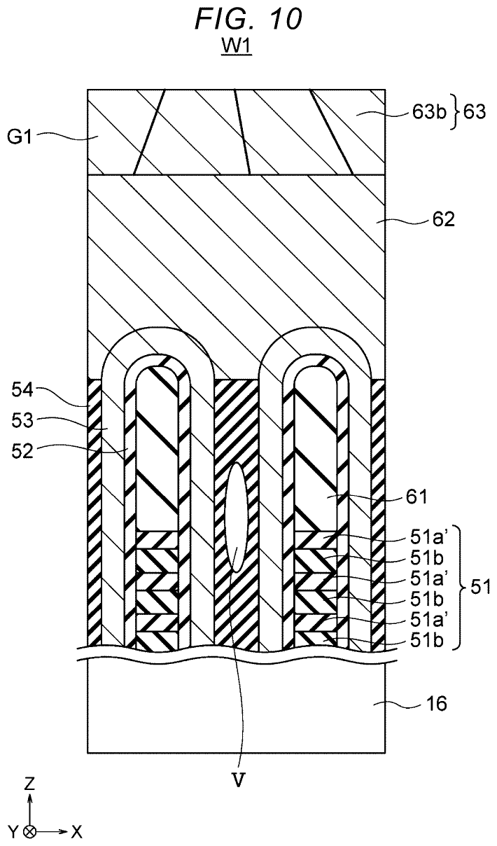

Next, the metal layer 64 is removed (FIG. 10). The metal layer 64 is removed using, for example, a chemical solution such as a mixed solution of sulfuric acid and hydrogen peroxide water (SH). According to the step shown in FIG. 10, the metal atoms M forming the metal layer 64 are removed after moving the metal atoms M from the channel semiconductor layer 53 and the cap semiconductor layer 62 to the surface of the getter layer 63.

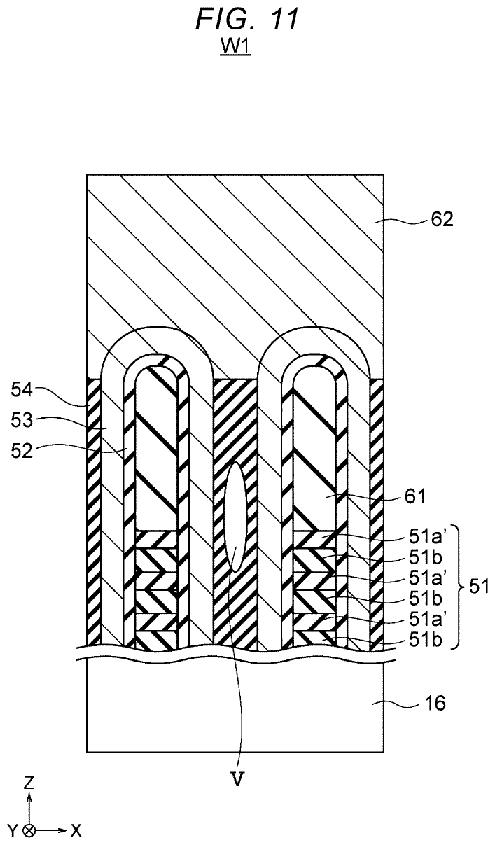

Next, the getter layer 63 is removed (FIG. 11). The getter layer 63 is removed, for example, by oxidizing the getter layer 63 or by ashing. According to the step shown in FIG. 11, the metal atoms M remaining in the getter layer 63 are removed after moving the metal atoms M from the channel semiconductor layer 53 and the cap semiconductor layer 62 into the getter layer 63.

According to the present embodiment, the getter layer 63 can be suitably removed by using a layer other than the Si layer as the getter layer 63. For example, when the channel semiconductor layer 53, the cap semiconductor layer 62, and the getter layer 63 are all Si layers, there is a concern that the cap semiconductor layer 62 and the channel semiconductor layer 53 may also be removed in a process of removing the getter layer 63. According to the present embodiment, the channel semiconductor layer 53 and the cap semiconductor layer 62 are made of a Si layer, and the getter layer 63 is made of a layer other than the Si layer. Therefore, a process of removing the getter layer 63 while the cap semiconductor layer 62 and the channel semiconductor layer 53 are left can be easily performed. In addition, when the channel semiconductor layer 53, the cap semiconductor layer 62, and the getter layer 63 are all Si layers, there is a concern that a process of removing the getter layer 63 may cause damage to the cap semiconductor layer 62 or the channel semiconductor layer 53. According to the present embodiment, the channel semiconductor layer 53 and the cap semiconductor layer 62 are made of a Si layer, and the getter layer 63 is made of a layer other than the Si layer, so that it is possible to reduce such damage (details will be described below).

The cap semiconductor layer 62 may be removed in a subsequent step or may not be removed. That is, the cap semiconductor layer 62 may or may not remain in the semiconductor device of the finished product. In the present embodiment, an example in which the cap semiconductor layer 62 is not left will be described. An example in which the cap semiconductor layer 62 remains will be described as a modification example of the present embodiment.

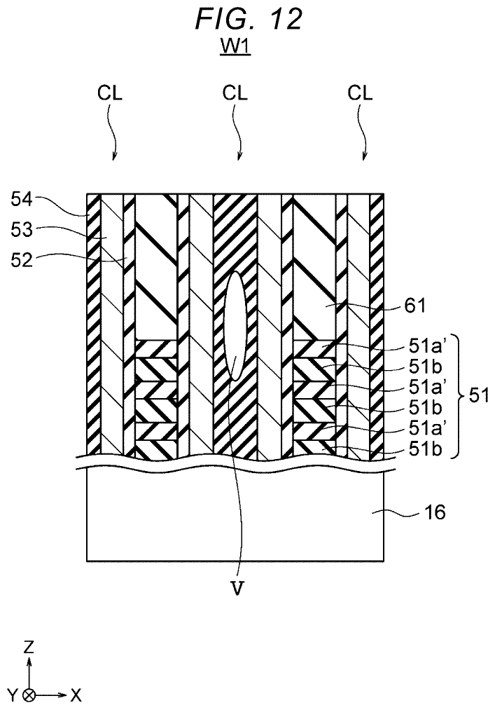

Next, the cap semiconductor layer 62 is removed (FIG. 12). The cap semiconductor layer 62 is removed by, for example, CMP. In the present embodiment, some of the channel semiconductor layer 53, the memory insulating film 52, the insulating film 61, and the like are also removed by the CMP. FIG. 12 shows a columnar portion CL formed in each of the memory holes H1 (FIG. 6).

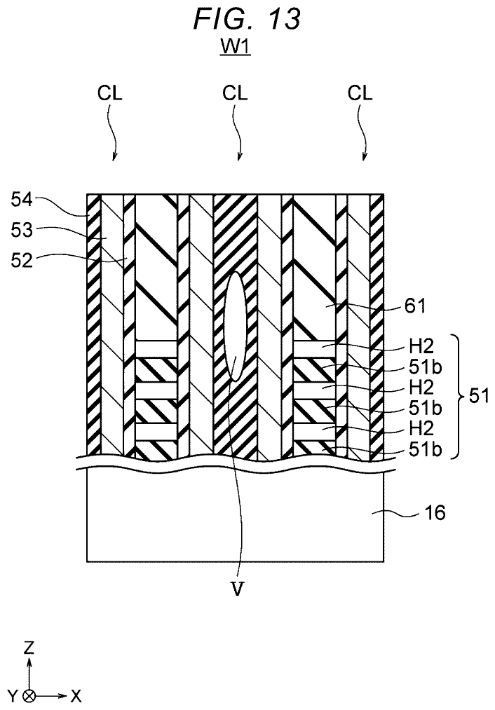

Next, a slit (not shown) is formed in the stacked film 51 by lithography and RIE, and the sacrificial layer 51a′ is removed by wet etching from the slit (FIG. 13). As a result, a plurality of cavities H2 are formed in the stacked film 51.

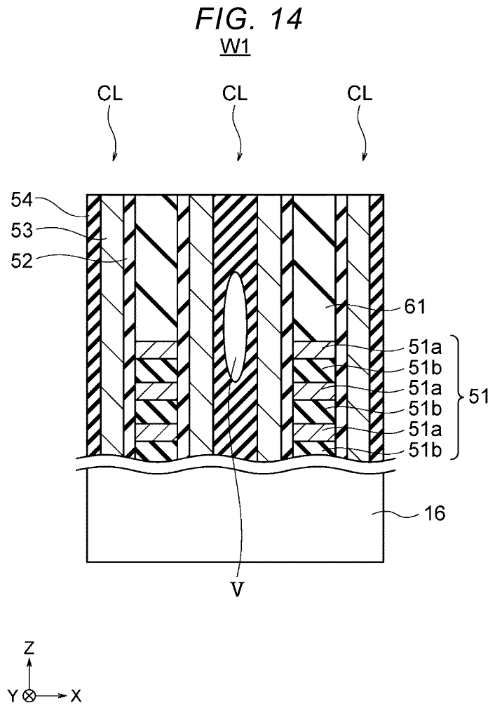

Next, the plurality of electrode layers 51a are formed in the plurality of cavities H2 (FIG. 14). As a result, the stacked film 51 including the plurality of electrode layers 51a and the plurality of insulating films 51b alternately is formed above the substrate 16. In this way, the memory cell array 11 shown in FIG. 3 is formed.

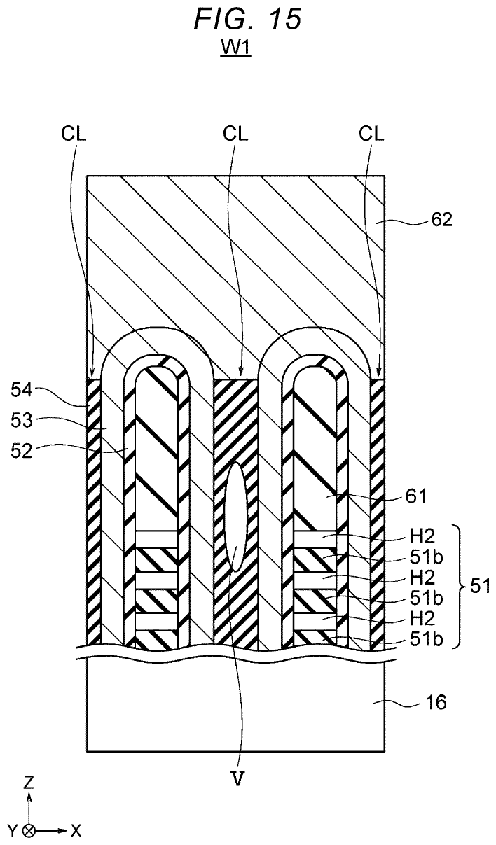

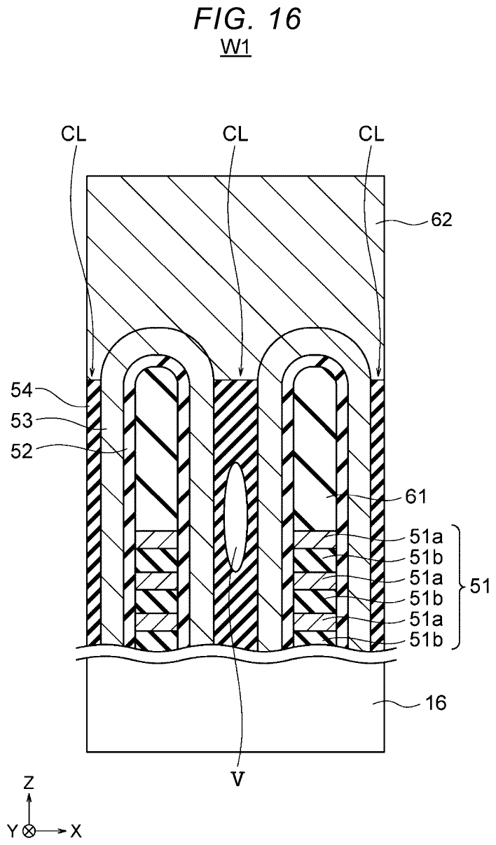

FIGS. 15 and 16 are cross-sectional views showing a method of manufacturing a semiconductor device according to a modification example of the first embodiment.

In the present modification example, the steps shown in FIGS. 5 to 11 are performed, but the step shown in FIG. 12 is not performed. Subsequently, the sacrificial layer 51a′ is removed in the same manner as in the step shown in FIG. 13 (FIG. 15), and the electrode layer 51a is formed in the same manner as in the step shown in FIG. 14 (FIG. 16). As a result, the stacked film 51 including the plurality of electrode layers 51a and the plurality of insulating films 51b is formed in a state where the cap semiconductor layer 62 remains. In this way, the memory cell array 11 shown in FIG. 3 is formed.

The cap semiconductor layer 62 is used, for example, as a wiring layer. The cap semiconductor layer 62 may be thinned (that is, partially removed) after the step shown in FIG. 11. For example, when the cap semiconductor layer 62 is used as a wiring layer, the cap semiconductor layer 62 may be thinned so that the thickness of the cap semiconductor layer 62 has a suitable thickness as the wiring layer.

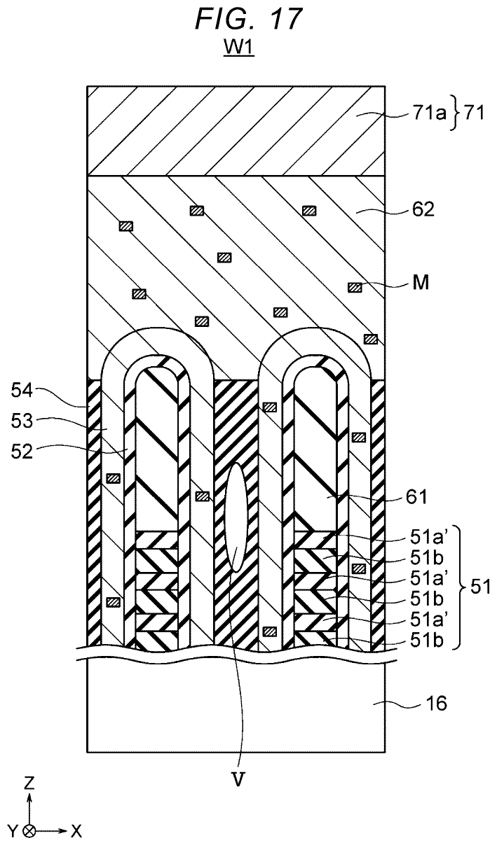

FIGS. 17 to 19 are cross-sectional views showing a method of manufacturing a semiconductor device of a comparative example of the first embodiment.

In this comparative example, first, the steps shown in FIGS. 5 to 7 are performed. In the step shown in FIG. 7, the getter layer 71 is formed instead of the getter layer 63. FIG. 17 shows an array wafer W1 including a getter layer 71 instead of the getter layer 63. The getter layer 71 is, for example, an N-doped Si layer containing nitrogen (N) atoms. The getter layer 71 is formed as an amorphous layer 71a in FIG. 17. The amorphous layer 71a is, for example, an amorphous silicon layer.

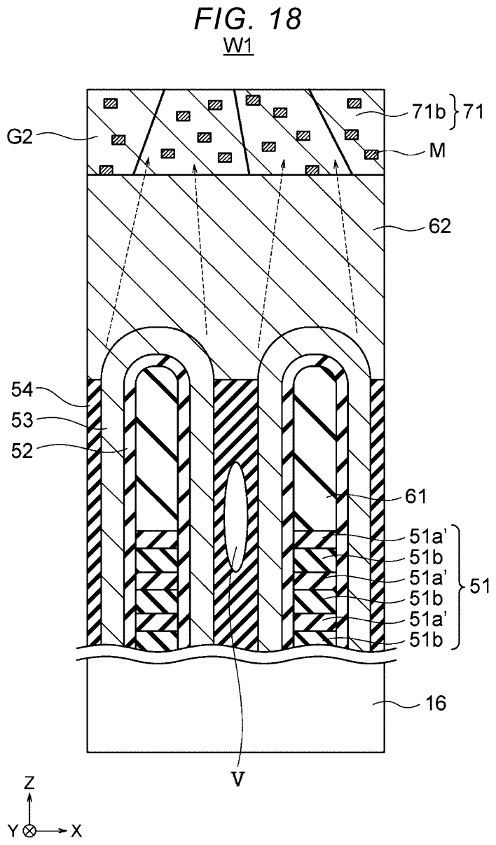

Next, the channel semiconductor layer 53, the cap semiconductor layer 62, the getter layer 71, and the like are annealed (FIG. 18). Thereby, at least some of the metal atoms M in the channel semiconductor layer 53 and the cap semiconductor layer 62 can be moved into the getter layer 71 (FIG. 18). The getter layer 71 changes from the amorphous layer 71a to the crystallization layer 71b during the annealing. The crystallization layer 71b is, for example, a polysilicon layer. FIG. 18 shows a plurality of crystal grains G2 provided in the crystallization layer 71b.

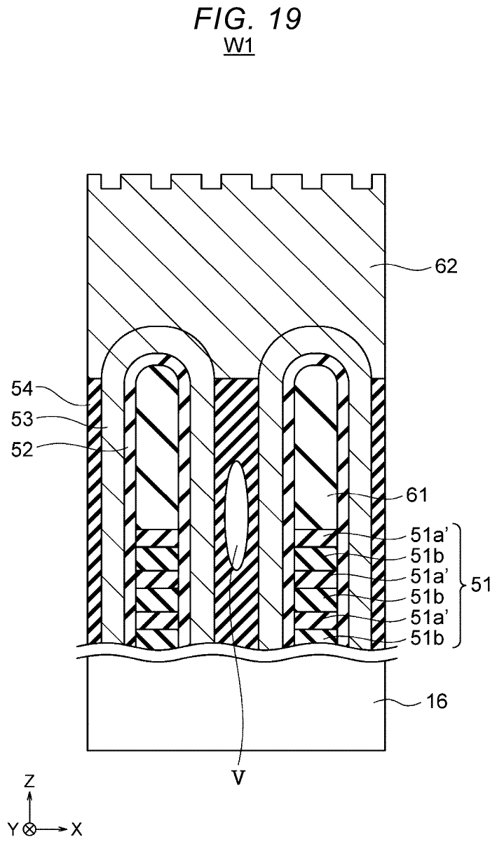

Next, the getter layer 71 is removed (FIG. 19). The getter layer 71 is removed, for example, by using a chemical solution such as phosphoric acid. According to the step shown in FIG. 19, the metal atoms M, which are moved from the channel semiconductor layer 53 and the cap semiconductor layer 62 into the getter layer 71, are removed. The subsequent steps of this comparative example are performed in the same manner as in the first embodiment or the modification example.

The getter layer 71 of this comparative example is a Si layer like the channel semiconductor layer 53 and the cap semiconductor layer 62. Therefore, it is difficult to selectively remove the getter layer 71 among the channel semiconductor layer 53, the cap semiconductor layer 62, and the getter layer 71. The getter layer 71 of this comparative example is removed by using a chemical solution such as phosphoric acid. In this case, there is a possibility that the surface of the cap semiconductor layer 62 may be damaged by the chemical solution. FIG. 19 schematically shows a state in which an uneven portion is generated on the surface of the cap semiconductor layer 62 when the getter layer 71 is removed using a chemical solution. The uneven portion is generated, for example, in the vicinity of a region in which the metal atoms M are contained at a high concentration. Damage to the cap semiconductor layer 62 or the channel semiconductor layer 53 may cause a leakage current and a decrease in a yield of the semiconductor device.

Meanwhile, the getter layer 63 of the present embodiment is a layer other than the Si layer. Therefore, according to the present embodiment, it is possible to reduce the leakage current and prevent the decrease in the yield. Further, according to the present embodiment, the getter layer 63 can be easily removed, and thus, for example, the number of manufacturing steps of the semiconductor device can be reduced, and the productivity of the semiconductor device can be improved.

The metal atoms M shown in FIG. 9 are sucked up to the surface of the getter layer 63 to form a metal layer 64. Therefore, it is considered that the C layer (getter layer 63) has an equal or higher ability to absorb the metal atoms M from the channel semiconductor layer 53 and the cap semiconductor layer 62 than the Si layer (getter layer 71).

As described above, in the present embodiment, the getter layer 63 is a layer other than the Si layer, and is, for example, a C layer or a Ge layer. Therefore, according to the present embodiment, the getter layer 63 can be suitably removed.

### Second Embodiment

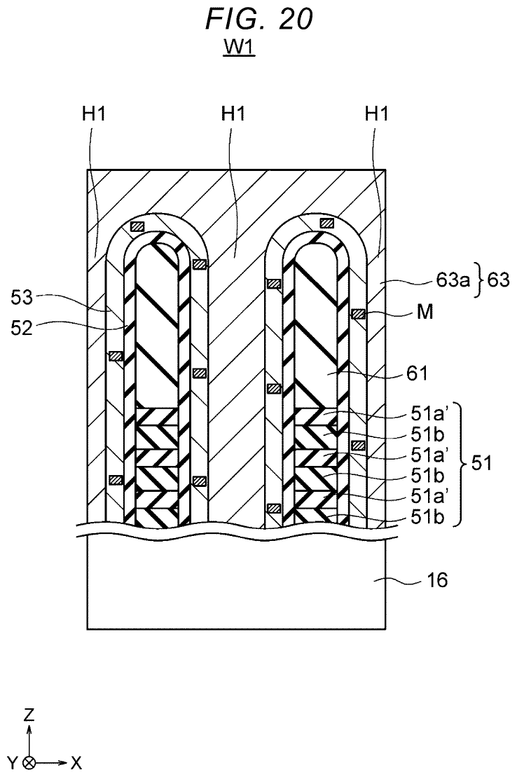

FIGS. 20 to 27 are cross-sectional views showing a method of manufacturing a semiconductor device according to a second embodiment.

In the present embodiment, first, the steps shown in FIGS. 5 to 7 are performed. In the step shown in FIG. 7, the step of forming the core insulating film 54 and the cap semiconductor layer 62 is omitted. As a result, the memory insulating film 52, the channel semiconductor layer 53, and the getter layer 63 are formed in order on the side surfaces of the stacked film 51 and the insulating film 61 in each memory hole H1 (FIG. 20). In FIG. 20, the memory insulating film 52, the channel semiconductor layer 53, and the getter layer 63 are further formed in order on the upper surface of the insulating film 61. The getter layer 63 according to the present embodiment may contain a void V in at least one of the memory holes H1, as in the core insulating film 54 according to the first embodiment.

The details of the getter layer 63 and the amorphous layer 63a according to the present embodiment are the same as those of the getter layer 63 and the amorphous layer 63a according to the first embodiment. In the present embodiment, the step of forming the core insulating film 54 and the cap semiconductor layer 62 is omitted, and thus, the lower surface and the side surface of the getter layer 63 are in contact with the upper surface and the side surface of the channel semiconductor layer 53. Therefore, it is desirable that the getter layer 63 of the present embodiment is formed on the channel semiconductor layer 53 such that an unnecessary film (for example, a SiO₂ film or a SiN film) is not interposed between the channel semiconductor layer 53 and the getter layer 63.

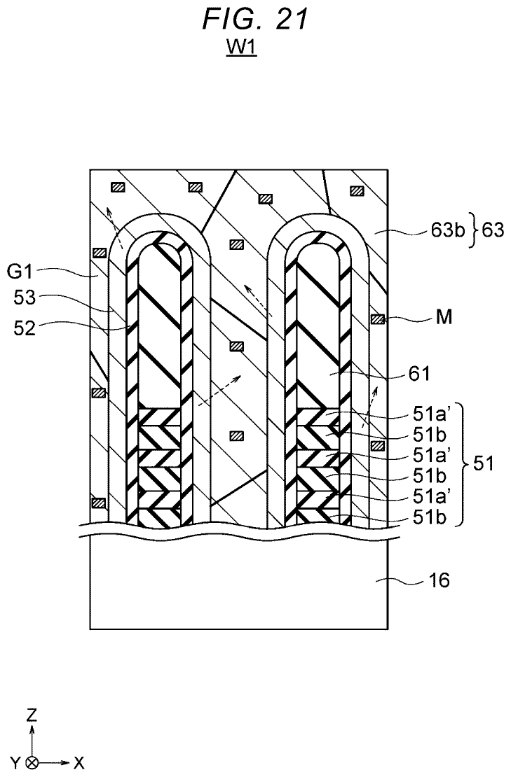

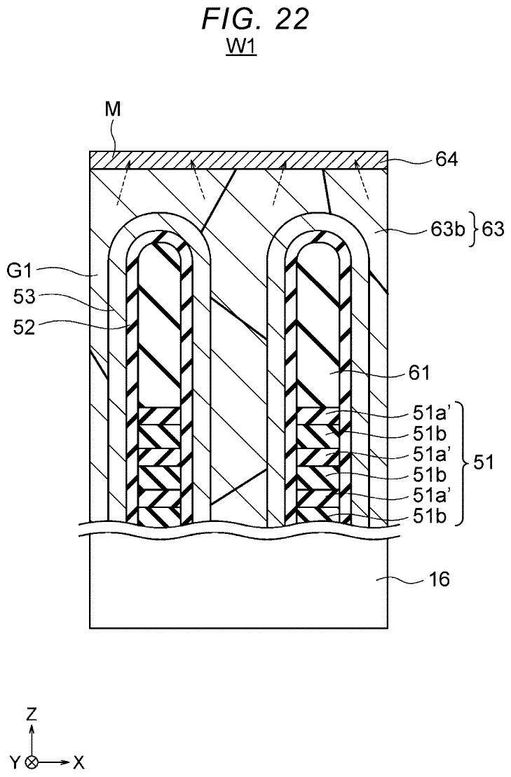

Next, the channel semiconductor layer 53, the getter layer 63, and the like are annealed (FIG. 21). As a result, at least some of the metal atoms M in the channel semiconductor layer 53 can be moved to the inside of the getter layer 63 (FIG. 21), and all or some of these metal atoms M can be moved to the surface (upper surface) of the getter layer 63 (FIG. 22). In FIG. 22, the metal atoms M move to the surface of the getter layer 63 to form the metal layer 64 containing the metal atoms M. In the present embodiment, the metal layer 64 is formed on the surface of the getter layer 63 during the annealing shown in FIGS. 21 and 22. As a result, at least some of the metal atoms M in the channel semiconductor layer 53 is removed from the channel semiconductor layer 53, and the concentration of the metal atoms M in the channel semiconductor layer 53 is reduced.

The getter layer 63 changes from the amorphous layer 63a to the crystallization layer 63b during the annealing shown in FIGS. 21 and 22. The details of the crystallization layer 63b according to the present embodiment are the same as those of the crystallization layer 63b according to the first embodiment. In addition, the details of the annealing shown in FIGS. 21 and 22 are the same as the annealing shown in FIGS. 8 and 9.

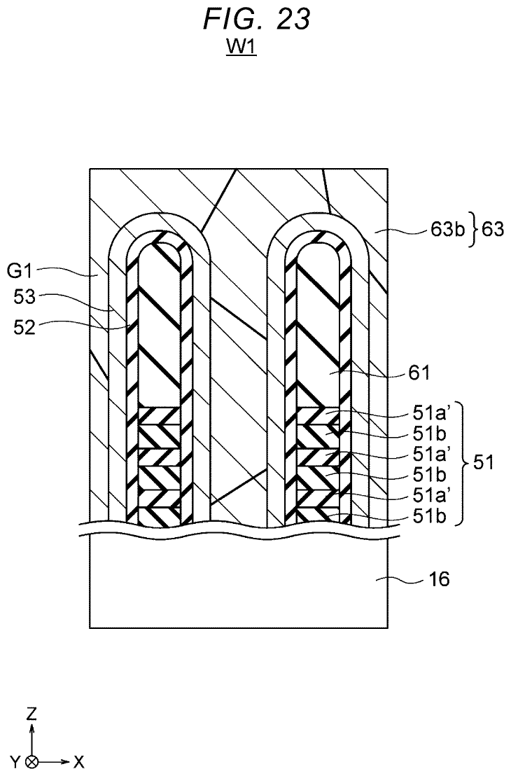

Next, the metal layer 64 is removed (FIG. 23). The step shown in FIG. 23 is performed in the same manner as the step in FIG. 10.

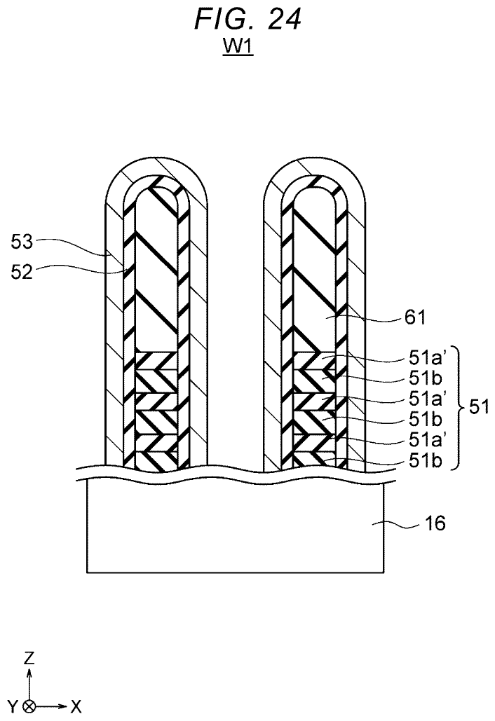

Next, the getter layer 63 is removed (FIG. 24). The step shown in FIG. 24 is performed in the same manner as the step shown in FIG. 11.

According to the present embodiment, the getter layer 63 can be suitably removed by using a layer other than the Si layer as the getter layer 63. For example, when both the channel semiconductor layer 53 and the getter layer 63 are Si layers, there is a concern that the channel semiconductor layer 53 may also be removed in a process of removing the getter layer 63. According to the present embodiment, the channel semiconductor layer 53 is made of the Si layer, and the getter layer 63 is made of a layer other than the Si layer. Therefore, the process of removing the getter layer 63 while the channel semiconductor layer 53 is left can be easily performed. In addition, as described in the first embodiment, when both the channel semiconductor layer 53 and the getter layer 63 are Si layers, there is a concern that the process of removing the getter layer 63 may cause damage to the channel semiconductor layer 53. For example, there is a concern that the uneven portion as shown in FIG. 19 may occur on the surface of the channel semiconductor layer 53. According to the present embodiment, by forming the channel semiconductor layer 53 as the Si layer and the getter layer 63 as the layer other than the Si layer, it is possible to reduce the damage.

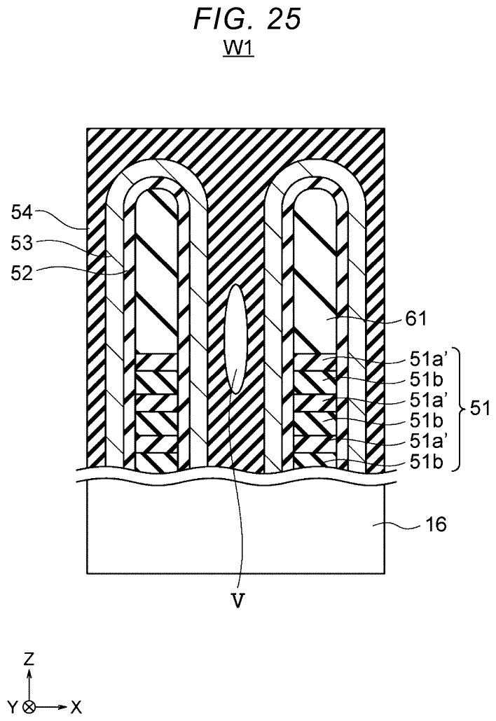

Next, the core insulating film 54 is formed on the entire surface of the substrate 16 (FIG. 25). As a result, the core insulating film 54 is formed on the side surfaces of the stacked film 51 and the insulating film 61 in each memory hole H1 through the memory insulating film 52 and the channel semiconductor layer 53. In FIG. 25, the core insulating film 54 is further formed on the upper surface of the insulating film 61 through the memory insulating film 52 and the channel semiconductor layer 53. FIG. 25 further shows the void V formed in the core insulating film 54.

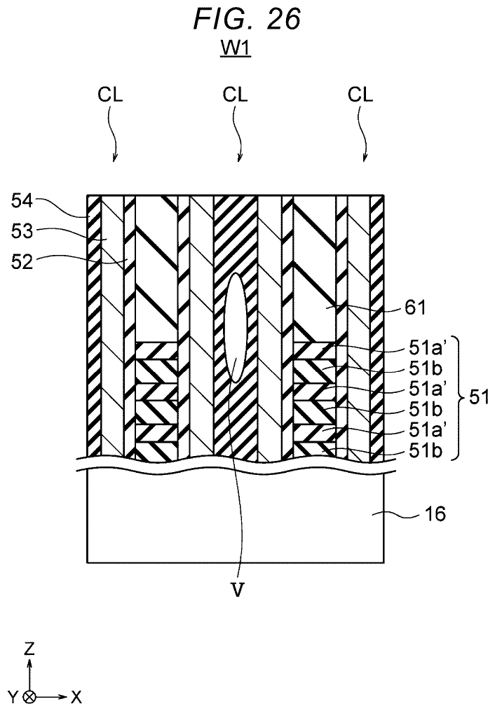

Next, the surface of the core insulating film 54 is flattened by CMP (FIG. 26). As a result, the core insulating film 54 outside the memory hole H1 is removed. In the present embodiment, some of the channel semiconductor layer 53, the memory insulating film 52, the insulating film 61, and the like are also removed by the CMP. FIG. 26 shows the columnar portion CL formed in each memory hole H1. The subsequent steps of the present embodiment are performed in the same manner as in the first embodiment.

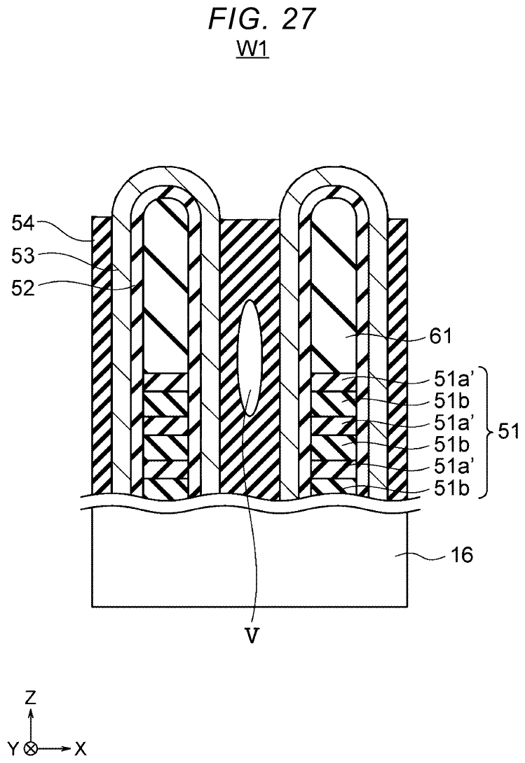

After the core insulating film 54 is formed on the entire surface of the substrate 16 (FIG. 25), a portion of the upper surface of the core insulating film 54 may be removed by etch back such that the upper surface of the channel semiconductor layer 53 becomes exposed therefrom (FIG. 27).

In the present embodiment, the cap semiconductor layer 62 may be formed on the channel semiconductor layer 53 in any step after the removal of the getter layer 63 and the formation of the core insulating film 54. The cap semiconductor layer 62 may be used as, for example, a wiring layer.

As described above, in the present embodiment, the getter layer 63 is a layer other than the Si layer, and is, for example, a C layer or a Ge layer. Therefore, according to the present embodiment, the getter layer 63 can be suitably removed in the same manner as in the first embodiment.

Here, the first embodiment and the second embodiment are compared. According to the second embodiment, the getter layer 63 is disposed near the channel semiconductor layer 53, and thus, the metal atoms M can be easily removed from the channel semiconductor layer 53. Meanwhile, when the void V is formed in the getter layer 63 of the second embodiment, there is a concern that the void V may hinder the movement of the metal atoms M in the getter layer 63. This is likely to become a problem when the aspect ratio of each memory hole H1 is high. According to the first embodiment, it is possible to avoid such a problem of the void V.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of manufacturing a semiconductor device, the method comprising:
forming a semiconductor layer containing a plurality of metal atoms;
forming a first layer other than a silicon (Si) layer on the semiconductor layer as a layer containing a main component element different from a main component element of the semiconductor layer;
annealing the semiconductor layer to move some of the metal atoms in the semiconductor layer into the first layer; and
removing the first layer after some of the metal atoms have been moved into the first layer.

2. The method of manufacturing a semiconductor device according to claim 1, wherein the semiconductor layer is a Si layer.

3. The method of manufacturing a semiconductor device according to claim 1, wherein the semiconductor layer includes a channel semiconductor layer.

4. The method of manufacturing a semiconductor device according to claim 1, wherein the first layer contains carbon (C) or germanium (Ge).

5. The method of manufacturing a semiconductor device according to claim 4, wherein the first layer further contains boron (B), phosphorus (P), arsenic (As), nitrogen (N), oxygen (O), or Si.

6. The method of manufacturing a semiconductor device according to claim 1, wherein the first layer contains carbon (C) or germanium (Ge) as the main component element.

7. The method of manufacturing a semiconductor device according to claim 6, wherein the first layer further contains boron (B), phosphorus (P), arsenic (As), nitrogen (N), oxygen (O), or Si as an impurity element.

8. The method of manufacturing a semiconductor device according to claim 1, wherein the first layer is formed directly on the semiconductor layer and, after the forming, neither a silicon oxide (SiO₂) film nor a silicon nitride (SiN) film is interposed between the semiconductor layer and the first layer.

9. The method of manufacturing a semiconductor device according to claim 1, wherein the metal atoms are nickel (Ni) atoms, cobalt (Co) atoms, manganese (Mn) atoms, titanium (Ti) atoms, chromium (Cr) atoms, ruthenium (Ru) atoms, iridium (Ir) atoms, palladium (Pd) atoms, iron (Fe) atoms, or platinum (Pt) atoms.

10. The method of manufacturing a semiconductor device according to claim 1, wherein the annealing of the semiconductor layer is performed at 300° C. to 1200° C.

11. The method of manufacturing a semiconductor device according to claim 1, wherein the annealing of the semiconductor layer is performed in an atmosphere containing an inert gas.

12. The method of manufacturing a semiconductor device according to claim 1, wherein the annealing of the semiconductor layer is performed in an atmosphere containing an argon (Ar) gas, a neon (Ne) gas, a xenon (Xe) gas, a nitrogen (N₂) gas, a hydrogen (H₂) gas, or a deuterium (D₂) gas.

13. The method of manufacturing a semiconductor device according to claim 1, wherein the first layer changes from an amorphous layer to a crystallization layer during the annealing of the semiconductor layer.

14. The method of manufacturing a semiconductor device according to claim 1, wherein a metal layer containing some of the metal atoms is formed on the surface of the first layer during the annealing of the semiconductor layer.

15. The method of manufacturing a semiconductor device according to claim 14, wherein the first layer contains C (carbon) as the main component element.

16. The method of manufacturing a semiconductor device according to claim 14, further comprising:
removing the metal layer, wherein the first layer is removed after the metal layer is removed.

17. The method of manufacturing a semiconductor device according to claim 16, wherein the first layer is removed by oxidizing or ashing the first layer.

18. A method of manufacturing a semiconductor device, the method comprising:
forming a semiconductor layer containing a plurality of metal atoms;
forming a first layer containing carbon (C) or germanium (Ge) on the semiconductor layer;
annealing the semiconductor layer to move some of the metal atoms in the semiconductor layer into the first layer; and
removing the first layer after some of the metal atoms have been moved into the first layer.

19. The method of manufacturing a semiconductor device according to claim 18, wherein the first layer contains C or Ge as a main component element.

20. The method of manufacturing a semiconductor device according to claim 19, wherein the first layer further contains boron (B), phosphorus (P), arsenic (As), nitrogen (N), oxygen (O), or Si as an impurity element.
